(19) United States
(12) Patent Application Publication
(10) Pub. No.: US 2020/0062968 A1
(43) Pub. Date: Feb. 27, 2020

(54) SURFACE TREATMENT AGENT AND SURFACE TREATMENT METHOD

(71) Applicant: TOKYO OHKA KOGYO CO., LTD., Kawasaki-shi (JP)

(72) Inventors: Emi UCHIDA, Kawasaki-shi (JP); Takumi NAMIKI, Kawasaki-shi (JP); Akira KUMAZAWA, Kawasaki-shi (JP)

(21) Appl. No.: 16/546,877

(22) Filed: Aug. 21, 2019

(30) Foreign Application Priority Data
Aug. 27, 2018 (JP) 2018-158546

(51) Int. Cl. C09D 5/00; C09D 7/20; C09D 7/63; H01L 21/30

(52) U.S. Cl. CPC C09D 5/00; H01L 21/30; C09D 7/63; C09D 7/20

(57) ABSTRACT

A surface treatment agent including: a silylating agent and a solvent, the solvent containing an aliphatic hydrocarbon.

### BACKGROUND OF THE INVENTION

### Field of the Invention

The present invention relates to a surface treatment agent and a surface treatment method.

Priority is claimed on Japanese Patent Application No. 2018-158546, filed on Aug. 27, 2018, the content of which is incorporated herein by reference.

### Description of Related Art

In recent years, tendencies of high integration and miniaturization of a semiconductor device has increased, and micronization and achievement of high aspect ratio of an inorganic pattern on a substrate are in progress.

On the other hand, a problem of so-called pattern collapse may arise. This pattern collapse is a phenomenon in which when forming a number of inorganic patterns in parallel on a substrate, adjacent patterns are brought close to each other such that they lean on each other, which causes breakage or separation of the patterns from a base portion. In a case where such pattern collapse occurs, this causes decrease in the product yield and reliability.

It is known that this pattern collapse occurs due to surface tension of a washing liquid when the washing liquid dries in washing treatment after the pattern formation. That is, when the washing liquid is removed in the drying process, a stress acts between the patterns based on the surface tension of the washing liquid to cause pattern collapse.

From such a background, application of drug solutions for forming a protective film as disclosed in Patent Literature 1 and Patent Literature 2 has been proposed. According to the drug solutions disclosed in the literature, it is possible to impart water repellency to the surface of a concave-convex pattern. As a result, it is supposed that the pattern collapse can be suppressed.

Although it is not the same as the pattern collapse, water repellency (silylation) is imparted to the surface of a substrate using a silylating agent such as hexamethyldisilazane (HMDS) (for example, refer to [Background of the Invention] of Patent Literature 3) in order to prevent partial loss of a resin pattern due to a developer by improving adhesiveness between the resin pattern, which becomes an etching mask, and the substrate.

Incidentally, in some devices used for washing or surface-treating a substrate or the like, a portion (liquid-contact portion) coming into contact with a washing liquid or a surface treatment liquid deteriorates due to a solvent contained in the washing liquid or the surface treatment liquid. Examples of the liquid-contact portion include a tank, a pipe, a connection portion, and a nozzle. An example of a member of the liquid-contact part includes polyvinyl chloride.

From such a background, a surface treatment liquid (drug solution for forming water repellent protective film) containing specific monoalkoxysilane, specific sulfonic acid, and a diluting solvent, in which the diluting solvent contains 80 to 100 mass % alcohol with respect to a 100 mass % diluting solvent in total has been proposed in Patent Literature 1.

### Documents of Related Art

[Patent Literature 1] Japanese Unexamined Patent Application, First Publication No. 2016-66785
[Patent Literature 2] Japanese Unexamined Patent Application, First Publication No. 2012-033873
[Patent Literature 3] Japanese Patent Application Publication No. 11-511900

### SUMMARY OF THE INVENTION

However, since the surface treatment liquid disclosed in Patent Literature 1 has a high alcohol content, in a case where a specific silylating agent such as N,N-dimethylaminotrimethylsilane (TMSDMA) or hexamethyldisilazane (HMDS) is used as the silylating agent, alcohol reacts with the silylating agent. Therefore, it has been found that the water repellent effect significantly decreases. For this reason, there is a problem that usable silylating agents are limited.

The present invention has been made in consideration of the above-described circumstance, and an object of the present invention is to provide a surface treatment agent that can impart water repellency (silylation) to the surface of an object to be treated at a high level without selecting the type of silylating agent while suppressing deterioration in a liquid-contact portion.

The present inventors have conducted extensive studies in order to solve the above-described problem. As a result, they have found that the above-described problems can be solved using a surface treatment agent in which a silylating agent and a specific solvent are combined, and have completed the present invention. Specifically, the present invention provides the following.

According to a first aspect of the present invention, there is provided a surface treatment agent including: a silylating agent (A) and a solvent (S), the solvent (S) containing an aliphatic hydrocarbon (S1).

According to a second aspect of the present invention, there is provided a surface treatment method comprising: subjecting an object to be treated to surface treatment using the surface treatment agent.

According to the present invention, it is possible to provide a surface treatment agent capable of imparting water repellency (silylation) to the surface of the object to be treated at a high level while suppressing deterioration in a liquid-contact portion.

### DETAILED DESCRIPTION OF THE INVENTION

(Surface Treatment Agent)

A surface treatment agent of the present embodiment includes: a silylating agent (A) and a solvent (S), in which the solvent (S) contains aliphatic hydrocarbon (S1).

An example of the “object to be treated” to be subjected to surface treatment includes a substrate used for producing a semiconductor device. Examples thereof include a silicon (Si) substrate, a silicon nitride (SiN) substrate, a silicon oxide film (Ox) substrate, a tungsten (W) substrate, a cobalt (Co) substrate, a titanium nitride (TiN) substrate, a tantalum nitride (TaN) substrate, a germanium (Ge) substrate, a silicon germanium (SiGe) substrate, an aluminum (Al) substrate, a nickel (Ni) substrate, a ruthenium (Ru) substrate, and a copper (Cu) substrate.

Examples of the “surface of a substrate” include the surface of an inorganic pattern provided on a substrate and the surface of an unpatterned inorganic layer in addition to the surface of a substrate itself.

Taking a silicon (Si) substrate as an example, a silicon oxide film such as a natural oxide film, a thermal oxide film, and a vapor-phase synthetic film (such as a CVD film) may be formed on the surface of the substrate, or a pattern may be formed on the silicon oxide film.

A pattern may be provided on the surface of the object to be treated in the present embodiment.

The shape of the pattern is not particularly limited, and can be, for example, a pattern shape generally formed in a semiconductor manufacturing step. The pattern shape may be a line pattern, a hole pattern, or a pattern including a plurality of pillars. The pattern shape preferably a pattern including a plurality of pillars. The shape of a pillar is not particularly limited, but examples thereof include a cylindrical shape and a polygonal prism shape (such as a square prism shape).

<Silylating Agent (A)>

The silylating agent (A) (hereinafter, also referred to as an (A) component”) is a component for silylating the surface of an object to be treated (for example, a semiconductor substrate) to improve the water repellency of the surface of the object to be treated (for example, a semiconductor substrate).

The (A) component of the present embodiment is not particularly limited, but it is possible to use any well-known silylating agents in the related art. Examples of the component (A) include the following components (A1) to (A3).

Component (A1): alkoxy monosilane compound having hydrophobic group bonded to silicon atom

Component (A2): compound having hydrophobic group bonded to silicon atom and leaving group bonded to silicon atom

Component (A3): cyclic silazane compound

<<Component (A1)>>

The component (A1) is an alkoxy monosilane compound having a hydrophobic group bonded to a silicon atom.

The alkoxy monosilane compound having a hydrophobic group bonded to a silicon atom means a compound which has one silicon atom, has at least one hydrophobic group bonded to the above-described silicon atom, and has at least one alkoxy group bonded to the above-described silicon atom.

In a case of using the alkoxy monosilane compound having a hydrophobic group bonded to a silicon atom as the silylating agent (A), it is possible to make the alkoxy monosilane compound having a hydrophobic group bind to the surface of an object to be treated. In the case where the alkoxy monosilane compound binds to an object to be treated, it is possible to form a monolayer, derived from the alkoxy monosilane compound, on the surface of the object to be treated. The monolayer is preferably a self-assembled monolayer (SAM) in which a network of siloxane bonds is formed on the surface of the object to be treated in a surface direction. The monolayer and the self-assembled monolayer will be described in detail below.

As the above-described hydrophobic group included in the above-described alkoxy monosilane compound, a chain aliphatic hydrocarbon group having 3 to 20 carbon atoms is preferable, a chain aliphatic hydrocarbon group having 6 to 18 carbon atoms is more preferable, a chain aliphatic hydrocarbon group having 7 to 12 carbon atoms is still more preferable, a chain aliphatic hydrocarbon group having 8 to 11 carbon atoms is particularly preferable, and a chain aliphatic hydrocarbon group having 8 to 10 carbon atoms is most preferable from the viewpoint of improving hydrophobicity.

The above-described chain aliphatic hydrocarbon group may be one in which a part or the whole of a hydrogen atom is substituted with a halogen atom (such as a fluorine atom) or may be linear or branched. The chain aliphatic hydrocarbon group is preferably a linear aliphatic hydrocarbon group in which a part or the whole of a hydrogen atom may be substituted with a fluorine atom.

An alkoxy group included in the above-described alkoxy monosilane compound is represented by General Formula RO— (R represents an alkoxy group). As the alkoxy group represented by R, a linear or branched alkyl group is preferable and a linear alkyl group is more preferable. In addition, the number of carbon atoms of the alkyl group represented by R is not particularly limited, but is preferably 1 to 10, more preferably 1 to 5, and still more preferably 1 or 2 from the viewpoint of controlling particularly during hydrolysis or condensation. Specific examples of the alkoxy group included in the alkoxy monosilane compound include a methoxy group, an ethoxy group, a propoxy group, an isopropoxy group, a butoxy group, a sec-butoxy group, and a t-butoxy group.

The above-described alkoxy monosilane compound is preferably a compound represented by Formula (1).

R¹ₙSiX₄₋ₙ (1)

[In the above-described general formula, R¹'s each independently represent a monovalent organic group; at least one of R¹'s is a chain aliphatic hydrocarbon group having 3 to 20 carbon atoms in which a part or the whole of a hydrogen atom may be substituted with a fluorine atom; X is an alkoxy group; and n is an integer of 1 to 3.] Examples of the monovalent organic group relating to R¹ include an alkyl group, an aromatic hydrocarbon group, an amino group, a monoalkylamino group, and a dialkylamino group.

Hereinafter, a case where R¹ is an organic group other than the chain aliphatic hydrocarbon group having 3 to 20 carbon atoms in which a part or the whole of a hydrogen atom may be substituted with a fluorine atom will be described.

As the alkyl group, a linear or branched alkyl group having 1 to 20 carbon atoms (preferably 1 to 8 carbon atoms) is preferable, and a methyl group, an ethyl group, an n-propyl group, and an isopropyl group are more preferable.

As the above-described aromatic hydrocarbon group, a phenyl group, a naphthyl group, a biphenylyl group, an anthryl group, and a phenanthrenyl group are preferable, a phenyl group and a naphthyl group are more preferable, and a phenyl group is particularly preferable.

The alkyl group contained in the above-described monoalkylamino group or dialkylamino group may contain a nitrogen atom, an oxygen atom, or a carbonyl group in a chain, or may be a linear alkyl group or a branched alkyl group. The number of carbon atoms of the alkyl group contained in the monoalkylamino group or the dialkylamino group is not particularly limited, but is preferably 1 to 20, more preferably 1 to 10, and particularly preferably 1 to 6.

Next, a case where R¹ is a chain aliphatic hydrocarbon group having 3 to 20 carbon atoms in which a part or the whole of a hydrogen atom may be substituted with a fluorine atom will be described.

As described above, the number of carbon atoms of the chain aliphatic hydrocarbon group is more preferably 6 to 18, still more preferably 7 to 12, particularly preferably 8 to 11, and most preferably 8 to 10.

The chain aliphatic hydrocarbon group may be linear or branched, and is preferably linear.

Suitable examples of the above-described chain aliphatic hydrocarbon group in which a part or the whole of a hydrogen atom may be substituted with a fluorine atom include linear alkyl groups such as an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, and an n-octadecyl group, and fluorinated linear alkyl group in which a hydrogen atom on each of the linear alkyl groups is substituted with fluorine.

An alkoxy group having 1 to 5 carbon atoms is preferable as X. Specific examples of X include alkoxy groups such as a methoxy group, an ethoxy group, an n-propoxy group, an isopropoxy group, an n-butoxy group, a sec-butoxy group, and a t-butoxy group.

Among these, a methoxy group, an ethoxy group, an isopropoxy group, or a butoxy group is preferable from the viewpoint of controlling particularly during hydrolysis or condensation.

In addition, the above-described alkoxy monosilane compound is preferably a trialkoxy monosilane compound.

The alkoxy monosilane compound exemplified above can be used alone or in combination of two or more thereof.

Specific examples of such an alkoxy monosilane compound include propyltrimethoxysilane, 3,3,3-trifluoropropyltrimethoxysilane, n-hexyltrimethoxysilane, n-octyltrimethoxysilane, n-methodicalness, and n-octadecyltrimethoxysilane, and n-hexyltrimethoxysilane, n-octyltrimethoxysilane, n-dodecyltrimethoxysilane, or n-octadecyltrimethoxysilane is preferable and n-octyltrimethoxysilane, n-dodecyltrimethoxysilane, or n-octadecyltrimethoxysilane is more preferable.

A monolayer can be formed on the surface of an object to be treated using the above-described alkoxy monosilane compound. In a case where a monolayer derived from an alkoxy monosilane compound having a hydrophobic group is formed on the surface of an object to be treated, the hydrophobicity of the surface of the object to be treated can be improved at a high level.

A network of siloxane bonds is preferably formed on the surface of the object to be treated in a surface direction in the monolayer from the viewpoint of particularly improving hydrophobicity at a high level. The monolayer is a so-called self-assembled monolayer. Residues derived from an alkoxy monosilane compound are densely contained in the self-assembled monolayer and bind to each other through siloxane bonds. Therefore, the monolayer can firmly bind to the surface of an object to be treated. As a result, hydrophobicity can be expressed at a particularly high level.

The self-assembled monolayer can be formed using a trialkoxy monosilane compound and/or a dialkoxy monosilane compound as a silylating agent (A) as described above.

It is possible to check formation of the above-described monolayer through, for example, a change in film thickness, a change in contact angle, and X-ray photoelectron spectroscopy (XPS).

The film thickness of the above-described monolayer can be set to be less than or equal to 20 nm, preferably set to be less than or equal to 10 nm, more preferably set to be less than or equal to 5 nm, and still more preferably set to be less than or equal to 3 nm, for example. The lower limit value thereof is not particularly limited as long as the effect of the present embodiment is not impaired, but is, for example, greater than or equal to 0.1 nm and typically greater than or equal to 0.5 nm.

<<Component (A2)>>

A component (A2) is a compound having a hydrophobic group bonded to a silicon atom and a leaving group bonded to a silicon atom. Examples of the component (A2) include compounds represented by General Formula (2).

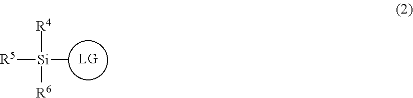

[In General Formula (2), R⁴, R⁵, and R⁶ each independently represent a hydrogen atom, a nitrogen-containing group, or an organic group, and the total number of carbon atoms contained in R⁴, R⁵, and R⁶ is greater than or equal to 1. LG represents a leaving group.]

The compounds represented by General Formula (2) can generate a chemical bond by reacting with a functional group (typically an —OH group, an —NH₂ group, or the like) on the surface of an object to be treated while eliminating a leaving group contained in the structure.

Examples of the leaving group include a halogen group or a nitrogen-containing group, with a nitrogen atom, which binds to a silicon atom in General Formula (2), a sulfoxy group or an acyloxy group, with an oxygen atom, which binds to a silicon atom in General Formula (2) or derivatives thereof, a hydrogen atom, and an azide group.

More specifically, it is possible to use compounds represented by General Formulae (3) to (6) as the compound which has a substituent and is represented by General Formula (2)

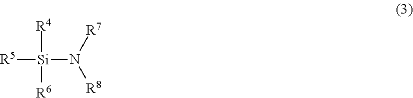

[In General Formula (3), R⁴, R⁵, and R⁶ are the same as those in General Formula (2) and R⁷ and R⁸ each independently represent a hydrogen atom, an alkyl group, a cycloalkyl group, an acetyl group, or a heterocycloalkyl group. R⁷ and R⁸ may bind to each other to form a ring structure containing a nitrogen atom, and a ring-constituting atom constituting the ring structure may contain a heteroatom other than the nitrogen atom.]

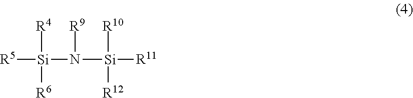

[In General Formula (4), R⁴, R⁵, and R⁶ are the same as those in General Formula (2), R⁹ represents a hydrogen atom, a methyl group, a trimethylsilyl group, or a dimethylsilyl group, R¹⁰, R¹¹, and R¹² each independently represent a hydrogen atom or an organic group, and the total number of carbon atoms contained in R¹⁰, R¹¹, and R¹² is greater than or equal to 1.]

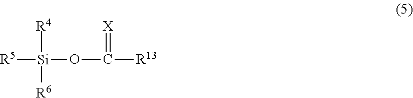

[In General Formula (5), R⁴, R⁵, and R⁶ are the same as those in General Formula (2), X represents O, CHR¹⁴, CHOR¹⁴, CR¹⁴R¹⁴, or NR¹⁵, R¹³, and R¹⁴ each independently represent a hydrogen atom, an alkyl group, a cycloalkyl group, a trialkylsilyl group, a trialkylsiloxy group, an alkoxy group, a phenyl group, a phenylethyl group, or an acetyl group, and R¹⁵ represents a hydrogen atom, an alkyl group, or a trialkylsilyl group.]

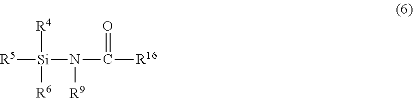

[In General Formula (6), R⁴, R⁵, and R⁶ are the same as those in General Formula (2), R⁹ is the same as that in General Formula (4), and R¹⁶ represents a hydrogen atom, an alkyl group, or a trialkylsilylamino group.]

In the alkyl group and the cycloalkyl group in General Formulae (3) to (6), a part or the whole of a hydrogen atom bonded to a carbon atom constituting the alkyl group and the cycloalkyl group may be substituted with a fluorine atom.

Examples of the compounds represented by General Formula (3) include N,N-dimethylaminotrimethylsilane (TMSDMA), N,N-dimethylaminodimethylsilane, N,N-dimethylaminomonomethylsilane, N,N-diethylaminotrimethylsilane, t-butylaminotrimethylsilane, allylaminotrimethylsilane, trimethylsilylacetamide, N,N-dimethylaminodimethylvinylsilane, N,N-dimethylaminodimethylpropylsilane, N,N-dimethylaminodimethyloctylsilane, N,N-dimethylaminodimethylphenylethylsilane, N,N-dimethylaminodimethylphenylsilane, N,N-dimethylaminodimethyl-t-butylsilane, N,N-dimethylaminotriethylsilane, trimethylsilanamine, monomethylsilyl imidazole, dimethylsilyl imidazole, trimethylsilyl imidazole, monomethyl triazole, dimethylsilyl triazole, trimethylsilyl triazole, N-(trimethylsilyl) dimethylamine, and trimethylsilyl morpholine.

Examples of the compounds represented by General Formula (4) include hexamethyldisilazane (HMDS), N-methylhexamethyldisilazane, 1,1,3,3-tetramethyldisilazane, 1,3-dimethyldisilazane, 1,2-di-N-octyltetramethyldisilazane, 1,2-divinyltetramethyldisilazane, heptamethyldisilazane, nonamethyltrisilazane, tris(dimethylsilyl)amine, tris(trimethylsilyl)amine, heptamethyldisilazane, pentamethylvinyldisilazane, pentamethylpropyldisilazane, pentamethylphenylethyldisilazane, pentamethyl-t-butyldisilazane, pentamethylphenyldisilazane, and trimethyltriethyldisilazane.

Examples of the silylating agent represented by General Formula (5) include trimethylsilyl acetate, dimethylsilyl acetate, monomethylsilyl acetate, trimethylsilyl propionate, trimethylsilyl butyrate, and trimethylsilyloxy-3-pentene-2-one.

Examples of the silylating agent represented by General Formula (6) include bis(trimethylsilyl) urea, N-trimethylsilylacetamide, and N-methyl-N-trimethylsilyltrifluoroacetamide.

In addition, among the compounds represented by General Formula (4), a compound having a hydrogen atom as R⁴ and/or R^{th} is also a preferred example.

In a case of using such a compound, it is considered that it is easy to form a network between molecules after the compound is developed on an object to be treated.

With such a contribution, once the compound binds to the surface of an object to be treated, there is a tendency that the compound is hardly removed even if it is subjected to a heating step.

In addition, among the compounds represented by General Formula (3), a silazane compound which has a nitrogen-containing group as R⁵ and is represented by General Formula (3-a) and in which two nitrogen atoms bind to a silicon atom is preferably used.

In a case where such a compound is used, the two nitrogen atoms contained in the compound can respectively form chemical bonds with respect to functional groups on the surface of the object to be treated. That is, two bonds of one silicon atom can bind to the object to be treated, and therefore, it is possible to form a firmer bond between a silylating agent (A) and the object to be treated.

Furthermore, in the case where it is possible to form a firm bond in this manner, once the silylating agent binds to the surface of an object to be treated, there is a tendency that the silylating agent is hardly removed even if it is subjected to a heating step.

In addition, as is defined below, R⁴ and R⁶ in General Formula (3-a) may be a nitrogen-containing group similarly to R⁵ in General Formula (3), and an interaction between the silylating agent and the object to be treated may be enhanced depending on the application.

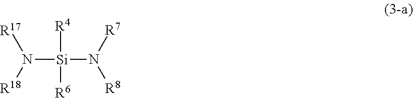

[In General Formula (3-a), R⁴ and R⁶ each independently represent a hydrogen atom, a nitrogen-containing group, or an organic group, and the total number of carbon atoms contained in R⁴ and R⁶ is greater than or equal to 1. R⁷, R⁸, R′⁷, and R¹⁸ each independently represent a hydrogen atom, an alkyl group, a cycloalkyl group, an acetyl group, or a heterocycloalkyl group. R⁷ and R⁸ or R¹⁷ and R¹⁸ may bind to each other to form a ring structure containing a nitrogen atom, and a ring-constituting atom constituting the ring structure may contain a heteroatom other than the nitrogen atom.]

In addition, in a case of paying attention to a substituent bonded to a silicon atom, a silylating agent in which a so-called bulky substituent having large number of carbon atoms contained in the substituent binds to a silicon atom is preferably used. In a case where the surface treatment agent contains such a silylating agent, it is possible to increase the hydrophobicity of the surface of an object to be treated which has been treated with the surface treatment agent.

For this reason, the total number of carbon atoms contained in R⁴, R⁵, and R⁶ in General Formula (2) is preferably greater than or equal to 3. Among these, it is more preferable that any one of R⁴, R⁵, or R⁶ in General Formula (2) is an organic group (hereinafter, referred to as a “specific organic group” in this paragraph) having two or more carbon atoms and the remaining two each independently represent a methyl group or an ethyl group. Examples of the specific organic group include an alkyl group having 2 to 20 carbon atoms which may be branched and/or substituted, a vinyl group which may be substituted, and an aryl group which may be substituted. The number of carbon atoms of the specific organic group is more preferably 2 to 12, still more preferably 2 to 10, and particularly preferably 2 to 8.

From such a viewpoint, preferred examples of the above-described silylating agent which has a substituent and is represented by General Formula (2) include N,N-dimethylaminodimethylvinylsilane, N,N-dimethylaminodimethylpropylsilane, N,N-dimethylaminodimethyloctylsilane, N,N-dimethylaminodimethylphenylethylsilane, N,N-dimethylaminodimethylphenylsilane, N,N-dimethylaminodimethyl-t-butylsilane, N,N-dimethylaminotriethylsilane, and N,N-dimethylaminotrimethylsilane (TMSDMA).

<<Component (A3)>>

A Component (A3) is a cyclic silazane compound.

Examples of the cyclic silazane compound include cyclic disilazane compounds such as 2,2,5,5-tetramethyl-2,5-disila-1-azacyclopentane, 2,2,6,6-tetramethyl-2,6-disila-1-azacyclohexane; cyclic trisilazane compounds such as 2,2,4,4,6,6-hexamethylcyclotrisilazane and 2,4,6-trimethyl-2,4,6-trivinylcyclotrisilazane; cyclic tetrasilazane compounds such as 2,2,4,4,6,6,8,8-octamethylcyclotetrasilazane.

Among such cyclic silazane compounds, a compound having a partial structure in which two or more nitrogen-containing groups bind to one silicon atom can be suitably used. In this case, it is possible to form firmer bond between a silylating agent and an object to be treated similarly to General Formula (3-a), and once the silylating agent has bound to the object to be treated, there is a tendency that the silylating agent is hardly removed even if it is subjected to a heating step.

<<Other Silylating Agents>>

A silylating agent other than the above-described components (A1) to (A3) may be used as the component (A). Examples of other silylating agents include compounds represented by General Formulae (7), (8), or (9).

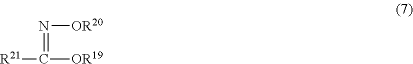

[In General Formula (7), R¹⁹ and R²⁰ each independently represent a hydrogen atom, an alkyl group, and a trialkylsilyl group, at least one of R¹⁹ or R²⁰ represents a trialkylsilyl group, and R²¹ represents an aliphatic hydrocarbon group which has 1 to 10 carbon atoms and in which a part or the whole of a hydrogen atom may be substituted with a fluorine atom.]

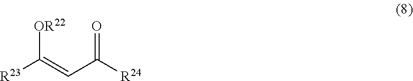

[In General Formula (8), R²² represents a trialkylsilyl group and R²³ and R²⁴ each independently represent a hydrogen atom or an organic group.]

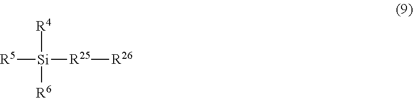

[In General Formula (9), R⁴, R⁵, and R⁶ are the same as those in General Formula (2), R²⁵ represents a single bond or an organic group, and R²⁶ is not present or, if present, represents —SiR²⁷R²⁸R²⁹. R²⁷, R²⁸, and R²⁹ each independently represent a hydrogen atom, a nitrogen-containing group, or an organic group.]

Examples of the compounds represented by Formula (7) include bis(trimethylsilyl) trifluoroacetamide, trimethylsilylmethylacetamide, and bistrimethylsilylacetamide, and an example of the compounds represented by Formula (8) includes 2-trimethylsiloxy penta-2-en-4-one. Examples of the compounds represented by Formula (9) include 1,2-bis(dimethylchlorosilyl) ethane and t-butyldimethylchlorosilane.

The silylating agents exemplified above may be used as the component (A) contained in the surface treatment agent alone or in combination of two or more thereof.

Among the above, as the component (A), the component (A2) is preferable, and the compounds represented by General Formula (3) and the compounds represented by General Formula (4) are more preferable from the viewpoint of easiness of availability or good handleability.

The content of the component (A) contained in the surface treatment agent of the present embodiment is not particularly limited as long as the effect of the present embodiment is not impaired, but a lower limit value of the content of the component (A) with respect to the total amount of the surface treatment agent is preferably greater than or equal to 0.001 mass %, more preferably greater than or equal to 0.01 mass %, still more preferably greater than or equal to 0.1 mass %, particularly preferably greater than or equal to 0.5 mass %, and most preferably greater than or equal to 1.0 mass %.

In a case where the content of the component (A) is greater than or equal to the lower limit values, it is possible to further improve the water repellency of the surface of the object to be treated.

The upper limit value of the content of the component (A) in the above-described surface treatment agent is preferably less than or equal to 30 mass %, more preferably less than or equal to 15 mass %, and still more preferably less than or equal to 10 mass %.

In a case where the content of the component (A) is less than or equal to the upper limit values, it is easy to obtain a surface treatment agent having superior handleability.

<Solvent (S)>

The surface treatment agent of the present embodiment contains a solvent (S) (hereinafter, also referred to as a “component (S)”) which contains aliphatic hydrocarbon (S1).

<<Aliphatic Hydrocarbon (S1)>>

Aliphatic hydrocarbon (S1) (hereinafter, also referred to as a “component (S1)”) does not have a hydroxyl group while suppressing deterioration in a liquid-contact portion. Therefore, even in a case where a silylating agent which easily reacts with alcoholic hydroxyl group such as N,N-dimethylaminotrimethylsilane (TMSDMA) and hexamethyldisilazane (HMDS) is used, it is possible to impart water repellency (silylation) to the surface of an object to be treated at a high level while suppressing the reaction with the silylating agent.

The component (S1) may be either linear, branched, or cyclic. The number of carbon atoms of the aliphatic hydrocarbon (S1) is not particularly limited, but is preferably 6 to 20, more preferably 6 to 14, and still more preferably 8 to 12.

The component (S1) may be saturated aliphatic hydrocarbon or unsaturated aliphatic hydrocarbon, but is preferably saturated aliphatic hydrocarbon.

Specific examples of linear saturated aliphatic hydrocarbon with 6 to 20 carbon atoms include n-hexane, n-heptane, n-octane, n-nonane, n-decane, n-undecane, n-dodecane, n-tridecane, n-tetradecane, n-pentadecane, n-hexadecane, n-heptadecane, n-octadecane, n-nonadecane, and n-icosane.

Specific examples of branched saturated aliphatic hydrocarbon with 6 to 20 carbon atoms include 2-methylpentane, 3-methylpentane, 2,2-dimethylbutane, 2,3-dimethylbutane, 2-methylhexane, 3-methylhexane, 2,3-dimethylpentane, 2,4-dimethylpentane, 2,2,3-trimethylpentane, 2,2,4-trimethylpentane, 3,4-diethylhexane, 2,6-dimethyloctane, 3,3-dimethyloctane, 3,5-dimethyloctane, 4,4-dimethyloctane, 3-ethyl-3-methylheptane, 2-methylnonane, 3-methylnonane, 4-methylnonane, 5-methylnonane, 2-methylundecane, 3-methylundecane, 2,2,4,6,6-pentamethylheptane, and 2,2,4,4,6,8,8-heptamethylnonane.

Specific examples of cyclic saturated aliphatic hydrocarbon with 6 to 20 carbon atoms include decalin, cyclohexane, methylcyclohexane, ethylcyclohexane, 1,2-dimethylcyclohexane, 1,3-dimethylcyclohexane, 1,4-dimethylcyclohexane, propylcyclohexane, isopropylcyclohexane, 1,2-methylcyclohexane, 1,3-methylethylcyclohexane, 1,4-methylethylcyclohexane, 1,2,3-trimethylcyclohexane, 1,2,4-trimethylcyclohexane, or 1,3,5-trimethylcyclohexane.

Among the above, the component (S1) is preferably linear aliphatic hydrocarbon with 6 to 20 carbon atoms and still more preferably linear aliphatic hydrocarbon with 8 to 12 carbon atoms. Specific examples thereof include n-octane, n-nonane, n-decane, n-undecane, or n-dodecane.

The aliphatic hydrocarbon (S1) contained in the surface treatment agent may be used alone or in combination of two or more thereof.

The content of the component (S1) contained in the component (S) with respect to the total amount of the component (S) is preferably greater than or equal to 50 mass % and more preferably greater than or equal to 80, and all the component (S) may be the component (S1).

In a case where the content of the component (S1) contained in the component (S) is greater than or equal to the lower limit values, even if a solvent other then the component (S1) is contained, it is possible to impart water repellency (silylation) to the surface of an object to be treated at a high level without selecting the type of silylating agent. Therefore, a liquid-contact portion is less likely to deteriorate.

<<Other Solvents>>

The component (S) may contain solvents other than the above-described component (S1). Examples of other solvents include: sulfoxides such as dimethyl sulfoxide; sulfones such as dimethyl sulfone, diethyl sulfone, bis(2-hydroxyethyl) sulfone, and tetramethylene sulfone; amides such as N,N-dimethylformamide, N-methylformamide, N,N-dimethylacetamide, N-methylacetamide, N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; other ethers such as dimethylglycol, dimethyldiglycol, dimethyltriglycol, methylethyl diglycol, diethylglycol, diethylene glycol dimethyl ether, diethylene glycol methyl ethyl ether, diethylene glycol diethyl ether, triethylene glycol dimethyl ether, tetraethylene glycol dimethyl ether, and propylene glycol monomethyl ether; (poly)alkylene glycol monoalkyl ether acetates such as ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monoethyl acetate, propylene glycol monomethyl ether acetate, and propylene glycol monoethyl ether acetate; other esters such as methyl 2-hydroxypropionate, ethyl 2-hydroxypropionate, ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxy acetate, ethyl hydroxy acetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl acetate, n-propyl acetate, isopropyl acetate, n-butyl acetate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate; ketones such as methyl ethyl ketone, cyclohexanone, 2-heptanone, 3-heptanone; lactones such as β-propyrolactone, γ-butyrolactone, and δ-pentyrolactone; aromatic hydrocarbons such as benzene, toluene, xylene, 1,3,5-trimethylbenzene, and naphthalene; terpenes such as β-menthane, diphenylmenthane, limonene, terpinene, bornane, norbomane, and pinane.

The content of the component (S) contained in the surface treatment agent of the present embodiment with respect to the total amount of the surface treatment agent is preferably 50 to 99.9 mass %, more preferably 80 to 99 mass %, and still more preferably 85 to 98 mass %.

<Optional Components>

The surface treatment agent of the present embodiment may contain components other than the above-described silylating agent (A) and solvent (S).

Examples of the optional components include a nitrogen-containing basic compound or a salt thereof (B) (hereinafter, also referred to as a “component (B)”), and a surfactant, an anti-foaming agent, or water which are not corresponding to the above-described silylating agent (A).

<<Nitrogen-Containing Basic Compound or Salt Thereof (B)>>

It is preferable that the surface treatment agent of the present embodiment further contains a component (B) in addition to the above-described silylating agent (A) and solvent (S).

Here, the nitrogen-containing basic compound is a compound containing a nitrogen atom that can acts as a base in its chemical structure.

Typical examples of the component (B) include a compound having a nitrogen-containing heterocyclic structure or a salt thereof (B1) (hereinafter, also referred to as a “component (B1)”), a compound represented by General Formula (B-2) or a salt thereof (B2) (hereinafter, also referred to as a “component (B2)”), and an amine compound having a phenoxy group or a salt thereof (B3) (hereinafter, also referred to as a “component (B3)”).

Nitrogen-Containing Heterocyclic Compound or Salt Thereof (B1)

In a case where the surface treatment agent of the present embodiment further contains the component (B1), a silylation reaction with respect to an object to be treated due to the silylating agent (A) is promoted by a catalytic action of the component (B1). As a result, in a case where the surface treatment time is the same as that in a case where the surface treatment agent does not contain the component (B1), it is possible to impart water repellency to the surface of the object to be treated at a high level. In a case where the water repellency is imparted to the same degree as in the case where the surface treatment agent does not contain the component (B1), it is possible to shorten the surface treatment time of the object to be treated.

The component (B1) is not particularly limited as long as it is a compound containing a nitrogen atom in a ring structure, or a salt thereof. The component (B1) may contain a heteroatom other than an oxygen atom and a nitrogen atom such as a sulfur atom in a ring structure.

Examples of a salt of a nitrogen-containing heterocyclic compound include a salt of an inorganic acid (such as hydrochloric acid, sulfuric acid, and nitric acid) of a nitrogen-containing heterocyclic compound, and a halogen salt.

The component (B1) is preferably an aromatic nitrogen-containing heterocyclic compound or a salt thereof. In the case where the component (B1) contains an aromatic nitrogen-containing heterocyclic compound or a salt thereof, it is possible to further improve the water repellency of the surface of an object to be treated which has been treated with a surface treatment agent.

In addition, in a case where the aromatic nitrogen-containing heterocyclic compound or a salt thereof is used as the component (B1) in this manner, an aspect in which an unshared electron pair having a nitrogen atom constituting a heterocycle is oriented outside a ring of an aromatic ring is preferable. By doing this, the component (B1) can appropriately act on a silylating agent (A), and therefore, the effect of the present embodiment can be stably brought about.

The component (B1) may be a compound or a salt thereof to which a plurality of, for example, two or more rings have bound through a single bond or a polyvalent, for example, di- or higher valent linking group. In this case, the plurality of, for example, two or more rings bonded through a linking group may contain at least one nitrogen-containing heterocycle.

Among the polyvalent linking group, a divalent linking group is preferable from the viewpoint of small steric hindrance between the rings. Specific examples of a divalent linking group include an alkylene group with 1 to 6 carbon atoms, —CO—, —CS—, —O—, —S—, —NH—, —N═N—, —CO—O—, —CO—NH—, —CO—S—, —CS—O—, —CS—S—, —CO—NH—CO—, —NH—CO—NH—, —SO—, and —SO₂—.

The number of rings contained in a compound to which the plurality of, for example, two or more rings have bound through a polyvalent linking group is preferably less than or equal to 4, more preferably less than or equal to 3, and still more preferably 2 from the viewpoint of easy preparation of a uniform surface treatment agent. The number of rings in a case of fused rings such as naphthalene rings is set, for example, to 2.

The component (B1) may be a compound or a salt thereof in which a plurality of rings are condensed. In this case, at least one ring among rings constituting a fused ring may be a nitrogen-containing heterocycle.

The number of rings contained in the component (B1) in which a plurality of rings are condensed is preferably less than or equal to 4, more preferably less than or equal to 3, and still more preferably 2 from the viewpoint of easy preparation of a uniform surface treatment agent.

The component (B1) preferably contains a fused polycyclic ring including a nitrogen-containing 5-membered ring or a nitrogen-containing 5-membered ring skeleton.

Suitable examples of a nitrogen-containing heterocyclic compound include pyridine, pyridazine, pyrazine, pyrimidine, triazine, tetrazine, pyrrole, pyrazole, imidazole, triazole, tetrazole, oxazole, isoxazole, thiazole, isothiazole, oxadiazole, thiadiazole, quinoline, isoquinoline, cinnoline, phthalazine, quinoxaline, quinazoline, indole, indazole, benzoimidazole, benzotriazole, benzooxazole, benzoisoxazole, benzothiazole, benzoisothiazole, benzooxadiazole, benzothiadiazole, saccharin, pyrrolidine, and piperidine.

Among these, pyrrole, pyrazole, imidazole, triazole, tetrazole, oxazole, isoxazole, thiazole, isothiazole, oxadiazole, thiadiazole, indole, indazole, benzoimidazole, benzotriazole, benzooxazole, benzoisoxazole, benzothiazole, benzoisothiazole, benzooxadiazole, benzothiadiazole, and saccharin are preferable and pyrrole, imidazole, triazole, tetrazole, and benzotriazole are more preferable.

Examples of a salt of a nitrogen-containing heterocyclic compound include hydrochlorides of the above-described compounds.

The above-described nitrogen-containing heterocyclic compound having a substituent or a salt thereof is preferably used as the component (B1).

Examples of the substituent which the nitrogen-containing heterocyclic compound or a salt thereof may have include an alkyl group, a cycloalkyl group, an alkoxy group, a cycloalkyloxy group, an aryl group, an aralkyl group, a halogenated alkyl group, an aliphatic acyl group, a halogenated aliphatic acyl group, an arylcarbonyl group, a carboxyalkyl group, a halogen atom, a hydroxyl group, a mercapto group, an alkylthio group, an amino group, a monoalkylamino group containing an alkyl group, a dialkylamino group containing an alkyl group, a nitro group, and a cyano group.

The nitrogen-containing heterocyclic compound or a salt thereof may have a plurality of substituents on a nitrogen-containing heterocycle. In the case where the number of substituents is plural, the plurality of substituents may be the same as or different from each other.

In a case where the substituents contain an aliphatic hydrocarbon ring, an aromatic hydrocarbon ring, and the like, the rings may further have the same substituents which the nitrogen-containing heterocyclic compound or a salt thereof may have.

The number of carbon atoms of an alkyl group as a substituent preferably 1 to 6, more preferably 1 to 4, and still more preferably 1 or 2. Specific examples of the alkyl group having 1 to 6 carbon atoms include a methyl group, an ethyl group, an n-propyl group, an isopropyl group, an n-butyl group, an isobutyl group, an sec-butyl group, a tert-butyl group, an n-pentyl group, and an n-hexyl group. Among these, a methyl group and an ethyl group are preferable and a methyl group is more preferable.

The number of carbon atoms of a cycloalkyl group as a substituent is preferably 3 to 8, more preferably 3 to 7, and still more preferably 4 to 6. Specific examples of the cycloalkyl group having 3 to 8 carbon atoms include a cyclopropyl group, a cyclobutyl group, a cyclopentyl group, a cyclohexyl group, a cycloheptyl group, and a cyclooctyl group.

The number of carbon atoms of an alkoxy group as a substituent preferably 1 to 6, more preferably 1 to 4, and still more preferably 1 or 2. Specific examples of the alkoxy group having 1 to 6 carbon atoms include a methoxy group, an ethoxy group, an n-propyloxy group, an isopropyloxy group, an n-butyloxy group, an isobutyloxy group, an sec-butyloxy group, a tert-butyloxy group, an n-pentyloxy group, and an n-hexyloxy group. Among these, a methoxy group and an ethoxy group are preferable and a methoxy group is more preferable.

The number of carbon atoms of a cycloalkyloxy group as a substituent is preferably 3 to 8, more preferably 3 to 7, and still more preferably 4 to 6. Specific examples of the cycloalkyl group having 3 to 8 carbon atoms include a cyclopropyloxy group, a cyclobutyloxy group, a cyclopentyloxy group, a cyclohexyloxy group, a cycloheptyloxy group, and a cyclooctyloxy group.

The number of carbon atoms of an aryl group as a substituent preferably 6 to 20 and more preferably 6 to 12. Specific examples of the aryl group having 6 to 20 carbon atoms include a phenyl group, an α-naphthyl group, a β-naphthyl group, a biphenyl-4-yl group, a biphenyl-3-yl group, a biphenyl-2-yl group, an anthracene-1-yl group, an anthracene-2-yl group, an anthracene-9-yl group, a phenanthrene-1-yl group, a phenanthrene-2-yl group, a phenanthrene-3-yl group, a phenanthrene-4-yl group, and a phenanthrene-9-yl group.

Among these, a phenyl group, an α-naphthyl group, a β-naphthyl group, a biphenyl-4-yl group, a biphenyl-3-yl group, and a biphenyl-2-yl group are preferable and a phenyl group is more preferable.

The number of carbon atoms of an aralkyl group as a substituent preferably 7 to 20 and more preferably 7 to 12. Specific examples of the aralkyl group having 7 to 20 carbon atoms include a benzyl group, a phenethyl group, a 3-phenyl-n-propyl group, a 4-phenyl-n-butyl group, an α-naphthylmethyl group, β-naphthylmethyl group, 2-(α-naphthyl)ethyl group, and 2-(β-naphthyl)ethyl group. Among these groups, a benzyl group and a phenethyl group are preferable and a benzyl group is more preferable.

Examples of a halogen atom contained in a halogenated alkyl group as a substituent include a fluorine atom, a chlorine atom, a bromine atom, and an iodine atom. The number of carbon atoms of a halogenated alkyl group as a substituent preferably 1 to 6, more preferably 1 to 4, and still more preferably 1 or 2.

Specific examples of the halogenated alkyl group having 1 to 6 carbon atoms include a chloromethyl group, a dichloromethyl group, a trichloromethyl group, a fluoromethyl group, a difluoromethyl group, a trifluoromethyl group, a 1,1-difluoroethyl group, a 2,2,2-trifluoroethyl group, and a pentafluoroethyl group.

The number of carbon atoms of an aliphatic acyl group as a substituent preferably 2 to 7, more preferably 2 to 5, and still more preferably 2 or 3. Specific examples of the aliphatic acyl group having 2 to 7 carbon atoms include an acetyl group, a propionyl group, a butanoyl group, a pentanoyl group, a hexanoyl group, and a heptanoyl group. Among these, an acetyl group and a propanoyl group are preferable and an acetyl group is more preferable.

Examples of a halogen atom contained in a halogenated aliphatic acyl group as a substituent include a fluorine atom, a chlorine atom, a bromine atom, and an iodine atom. The number of carbon atoms of a halogenated aliphatic acyl group as a substituent preferably 2 to 7, more preferably 2 to 5, and still more preferably 1 or 2. Specific examples of the halogenated alkyl group having 2 to 7 carbon atoms include a chloroacetyl group, a dichloroacetyl group, a trichloroacetyl group, a fluoroacetyl group, a difluoroacetyl group, a trifluoroacetyl group, and a pentafluoropropionyl group.

The number of carbon atoms of an arylcarbonyl group as a substituent preferably 7 to 20 and more preferably 7 to 13. Specific examples of the arylcarbonyl group having 7 to 20 carbon atoms include a benzoyl group, α-naphthoyl group, and β-naphthoyl group.

The number of carbon atoms of a carboxyalkyl group as a substituent preferably 2 to 7, more preferably 2 to 5, and still more preferably 2 or 3. Specific examples of the carboxyalkyl group having 2 to 7 carbon atoms include a carboxymethyl group, a 2-carboxyethyl group, a 3-carboxy-n-propyl group, a 4-carboxy-n-butyl group, a 5-carboxy-n-hexyl group, and a 6-carboxy-n-hexyl group. Among these, a carboxymethyl group is preferable.

Examples of a halogen atom include a fluorine atom, a chlorine atom, a bromine atom, and an iodine atom.

Among these, a fluorine atom, a chlorine atom, and a bromine atom are preferable and a chlorine atom and a bromine atom are more preferable.

The number of carbon atoms of an alkylthio group as a substituent preferably 1 to 6, more preferably 1 to 4, and still more preferably 1 or 2. Specific examples of the alkylthio group having 1 to 6 carbon atoms include a methylthio group, an ethylthio group, an n-propylthio group, an isopropylthio group, an n-butylthio group, an isobutylthio group, an sec-butylthio group, a tert-butylthio group, an n-pentylthio group, and an n-hexylthio group. Among these, a methylthio group and an ethylthio group are preferable and a methylthio group is more preferable.

Specific examples of an alkyl group contained in a monoalkylamino group containing an alkyl group or a dialkylamino group containing an alkyl group are the same as those of an alkyl group as the above-described substituent.

An ethylamino group and a methylamino group are preferable and a methylamino group is more preferable as the monoalkylamino group containing an alkyl group.

A diethylamino group and a dimethylamino group are preferable and a dimethylamino group is more preferable as the dialkylamino group.

Among the above, pyrrole, imidazole, triazole, tetrazole which may have an alkyl group or an aryl group, and benzotriazole are more preferable as the component (B1). Suitable specific examples of the component (B1) include the following compounds.

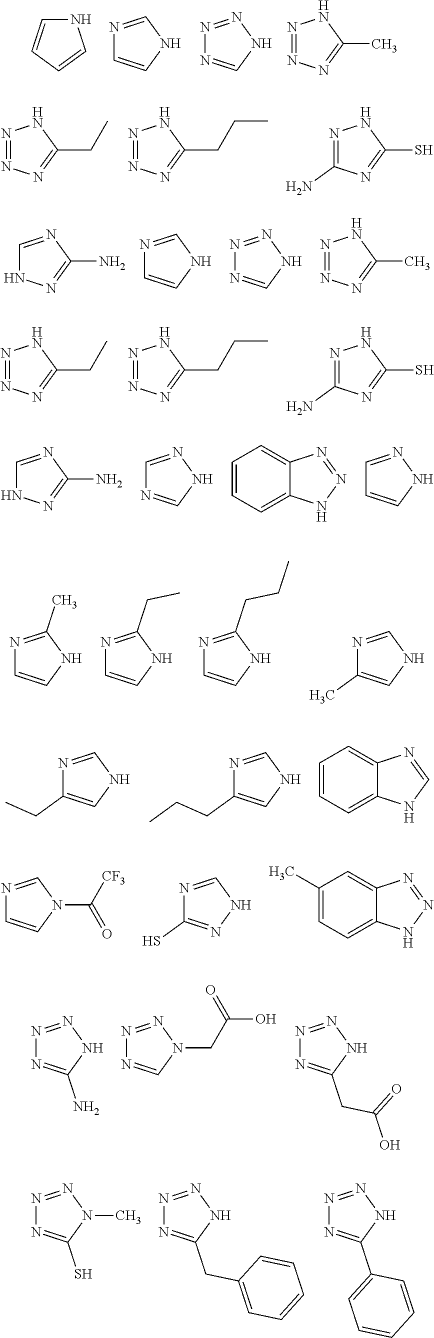

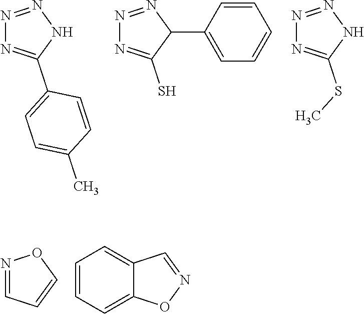

The component (B1) contained in the surface treatment agent may be used alone or in combination of two or more thereof.

Compound Represented by General Formula (B-2) or Salt Thereof (B2)

The surface treatment agent of the present embodiment may contain a compound represented by General Formula (B-2) or a salt thereof (B2).

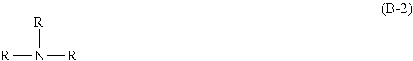

[In Formula (B-2), R's each independently represent a hydrogen atom, a hydroxyl group, or an organic group.]

Examples of an organic group of R in Formula (B-2) include an alkyl group which may be substituted, a cycloalkyl group which may be substituted, an aryl group which may be substituted, or an aralkyl group which may be substituted. Examples of the substituents include a hydroxy group, a carboxy group, an amino group, a halogen atom (such as a fluorine atom, a chlorine atom, and a bromine atom), and an alkoxy group.

The alkyl group of an organic group of R in Formula (B-2) may be linear or branched. The linear or branched alkyl group is preferably a linear or branched alkyl group having 1 to 40 carbon atoms and more preferably a linear or branched alkyl group having 6 to 20 carbon atoms.

The number of carbon atoms of a cycloalkyl group of an organic group of R in Formula (B-2) is preferably 3 to 20 and more preferably 5 to 15.

The number of carbon atoms of an aryl group of an organic group of R in Formula (B-2) is preferably 6 to 20 and more preferably 6 to 10. Specific examples thereof include a phenyl group or a naphthyl group.

The number of carbon atoms of an aralkyl group of an organic group of R in Formula (B-2) is preferably 7 to 20 and more preferably 7 to 11. A specific example thereof includes a benzyl group.

In addition, the component (B2) may be a salt of a compound represented by General Formula (B-2).

Examples of a salt of the compound include an inorganic acid (such as hydrochloric acid, sulfuric acid, and nitric acid) salt, a halogen salt, and a hydrochloric acid.

Specific examples of the compound represented by General Formula (B-2) include ammonia; primary amines such as hydroxylamine; ethylamine, n-propylamine, n-butylamine, 1-ethylbutylamine, 1,3-diaminopropane, and cyclohexylamine; secondary amines such as diethylamine, di-n-propylamine, di-n-butylamine, 4,4′-diaminodiphenylamine, diethylenetriamine, tetraethylenepentamine, and N-(2-aminoethyl) ethanolamine; tertiary amines such as dimethylethylamine, diethylmethylamine, triethylamine, tributylamine, triisopropylamine, and dicyclohexylmethylamine; aromatic amines such as N,N-dibutylaniline, N,N-dihexylaniline, 2,6-diisopropylaniline, and 2,4,6-tri(t-buthyl) aniline; alkanolamines such as monoethanolamine, diethanolamine, triethanolamine, diethylethanolamine, and propanolamine.

Specific examples of the salt of the compound represented by General Formula (B-2) include hydrochloride salts of the above-described compounds.

The component (B2) contained in the surface treatment agent may be used alone or in combination of two or more thereof.

Amine Compound Having Phenoxy Group or Salt Thereof (B3)

The compound (B3) is a compound including a phenoxy group at a terminal opposite to a nitrogen atom of an alkyl group contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an acyloxy group, and an aryloxy group, for example.

The component (B3) preferably has at least one oxyalkylene chain between a phenoxy group and a nitrogen atom. The number of oxyalkylene chains in a molecule is preferably 3 to 9 and more preferably 4 to 6. Among the oxyalkylene chains, —CH₂CH₂O— is particularly preferable.

A specific example thereof includes 2-[2-{2-(2,2-dimethoxy-phenoxyethoxy)ethyl}-bis-(2-methoxy ethyl)]-amine.

An amine compound having a phenoxy group can be obtained through extraction using an organic solvent such as ethyl acetate and chloroform after, for example, heating a primary or secondary amine having a phenoxy group and haloalkyl ether for reaction and adding an aqueous solution of strong bases such as sodium hydroxide, potassium hydroxide, and tetraalkylammonium thereto. In addition, an amine compound having a phenoxy group can also be obtained through extraction using an organic solvent such as ethyl acetate and chloroform after heating a primary or secondary amine and haloalkyl ether having a phenoxy group at a terminal for reaction and adding an aqueous solution of strong bases such as sodium hydroxide, potassium hydroxide, and tetraalkylammonium thereto.

The component (B3) contained in the surface treatment agent may be used alone or in combination of two or more thereof.

Other nitrogen-containing basic compounds may be used as the component (B) in the surface treatment agent of the present embodiment. Examples of the other nitrogen-containing basic compounds include a guanidine compound or a salt thereof.

The component (B) in the surface treatment agent of the present embodiment preferably contains the component (B1) among the above.

The content of the component (B) with respect to the total amount of the surface treatment agent of the present embodiment in a case where the surface treatment agent contains the component (B) is preferably 0.001 to 20 mass %, more preferably 0.01 to 10 mass %, still more preferably 0.03 to 5 mass %, and particularly preferably 0.05 to 3 mass %.

In a case where the content of the component (B) is greater than or equal to the lower limit values, it is possible to further improve the water repellency of the surface of the object to be treated.

In a case where the content of the component (B) is less than or equal to the upper limit values, the balance with other components becomes better.

According to the above-described surface treatment agent of the present embodiment, it is difficult to affect a liquid-contact portion since the aliphatic hydrocarbon (S1) is used as a solvent and it is possible to impart water repellency (silylation) to the surface of an object to be treated at a high level even using any silylating agent.

(Surface Treatment Method)

The surface treatment method according to the present embodiment is a surface treatment method in which surface treatment of an object to be treated is performed using the above-described surface treatment agent.

The surface treatment method according to the present embodiment imparts water repellency (silylation) to the surface of an object to be treated. Representative examples for the surface treatment include: (1) imparting water repellency to the surface of a substrate as an object to be treated to improve adhesiveness between a resin pattern, which is made of photoresist, and the substrate; and (2) imparting water repellency to the surface of an inorganic pattern included in an object to be treated to prevent pattern collapse during washing.

Examples of applying a surface treatment agent to the surface of an object to be treated include a spray method, a spin coating method, and an immersion method. The surface treatment time is not particularly limited, but is, for example, 1 to 60 seconds. After the surface treatment, the contact angle of water on the surface of the object to be treated is preferably 40 to 120 degrees and more preferably 60 to 100 degrees.

Devices used for surface treatment of an object to be treated are not particularly limited as long as these can apply a surface treatment agent on the object to be treated. An example of such a device include a device that can apply a surface treatment agent to the object to be treated through a spray method, a spin coating method, an immersion method, and the like. In addition, the liquid-contact portion is not particularly limited as long as it is a portion coming into contact with a surface treatment agent, and examples thereof include a tank in which the surface treatment agent is stored, a pipe through which a surface treatment agent passes, and a nozzle from which a surface treatment agent is discharged.

An example of an object to be treated to be subjected to surface treatment includes a substrate used for manufacturing a semiconductor device. In addition, examples of the surface of an object to be treated include the surface of an inorganic pattern provided on a substrate and the surface of an unpatterned inorganic layer in addition to the surface of a substrate itself.

An example of an inorganic pattern provided on a substrate includes an inorganic pattern formed by producing an etching mask on the surface of an inorganic layer present on the substrate through a photoresist method and is subsequently subjected to etching treatment. Examples of the inorganic layer include, in addition to a substrate itself, a layer made of an oxide of an element constituting a substrate and a layer which is formed on the surface of a substrate and formed of an inorganic substance such as silicon nitride, titanium nitride, or tungsten. Such an inorganic layer is not particularly limited, but an example thereof includes an inorganic layer formed in the process of manufacturing a semiconductor device.

According to the above-described surface treatment method of the present embodiment, it is possible to impart water repellency (silylation) to the surface of an object to be treated at a high level while suppressing deterioration in a liquid-contact portion when performing surface treatment of the object to be treated of an inorganic pattern.

The surface treatment method of the present embodiment is a useful method for a liquid-contact portion in a case of using, for example, a device including a member made of polyvinyl chloride.

[Optional Step]

The surface treatment method according to the present embodiment may include steps such as a washing step, a rinsing step, and a drying step.

<<Washing Step>>

The washing step is a step of previously washing the surface of an object to be treated.

The washing method is not particularly limited, but an example of the method for washing a semiconductor substrate includes a well-known RCA washing method. In the RCA washing method, first, a semiconductor substrate is immersed in an SC-1 solution of hydrogen peroxide and ammonium hydroxide to remove fine particles and an organic substance from the semiconductor substrate. Subsequently, the semiconductor substrate is immersed in hydrofluoric acid aqueous solution to remove a natural oxide film on the surface of the substrate. Thereafter, the semiconductor substrate is immersed in an acidic solution of an SC-2 solution of hydrogen peroxide and diluted hydrochloric acid to remove alkali ions or metal impurities which are insoluble in the SC-1 solution.

<<Rinsing Step>>

The rinsing step is a step of rinsing the surface of a water-repellent (silylated) object to be treated with a rinsing liquid.

In the rinsing step, the surface of a water-repellent (silylated) object to be treated is rinsed with a rinsing liquid to be described below. The rinsing method is not particularly limited, and a method generally used for washing a substrate in a semiconductor manufacturing step can be employed. Examples of such a method include a method for immersing an object to be treated in a rinsing liquid, a method for bringing steam of a rinsing liquid into contact with an object to be treated, and a method for supplying a rinsing liquid to an object to be treated while spinning the object to be treated. Among these, the method for supplying a rinsing liquid to an object to be treated while spinning the object to be treated is preferable as the rinsing method. In the method, the rotational speed of the spinning is, for example, 100 rpm to 5,000 rpm.

Rinsing Liquid

The rinsing liquid used in the rinsing step is not particularly limited, and a liquid generally used in a rinsing step of a semiconductor substrate can be used.

An example of the rinsing liquid includes a liquid containing an organic solvent.

Examples of the organic solvent include hydrocarbons, esters, ethers, ketones, halogen-containing solvents, sulfoxide solvents, alcohols, derivatives of polyhydric alcohol, and nitrogen-containing compound solvents.

The rinsing liquid may contain water instead of or together with the organic solvent.

The rinsing liquid may contain a well-known additive and the like. Examples of the well-known additive include a fluorine-based surfactant or a silicone-based surfactant.

Specific examples of the fluorine-based surfactant include, but are not limited thereto, commercially available fluorine-based surfactants such as BM-1000 and BM-1100 (all are manufactured by BM Chemie), Megafac F142D, Megafac F172, Megafac F173, and Megafac F183 (all are manufactured by DIC CORPORATION), Fluorad FC-135, Florard FC-170C, Florard FC-430, and Florard FC-431 (all are manufactured by Sumitomo 3M Limited), Surflon S-112, Surflon S-113, Surflon S-131, Surflon S-141, and Surflon S-145 (all are manufactured by Asahi Glass Co., Ltd.), SH-28PA, SH-190, SH-193, SZ-6032, and SF-8428 (all are manufactured by TORAY INDUSTRIES. INC.).

Specifically, it is possible to preferably use an unmodified silicone-based surfactant, a polyether-modified silicone-based surfactant, a polyester-modified silicone-based surfactant, an alkyl-modified silicone-based surfactant, an aralkyl-modified silicone-based surfactant, a reactive silicone-based surfactant, and the like as the silicone-based surfactant.

It is possible to use a commercially available silicone-based surfactant as the silicone-based surfactant. Specific examples of a commercially available silicone-based surfactant include Paintad M (manufactured by Dow Corning Toray Co., Ltd.), Topeka K1000, Topeka K2000, and Topeka K5000 (all are manufactured by TAKACHIHO SANGYO CO., LTD.), XL-121 (polyether-modified silicone-based surfactant manufactured by Clariant), and BYK-310 (polyester-modified silicone-based surfactant manufactured by BYK Chemie).

<<Drying Step>>

The drying step is a step of drying an object to be treated. It is possible to efficiently remove a rinsing liquid remaining in an object to be treated after the rinsing step by performing the drying step.

The method for drying an object to be treated is not particularly limited, and well-known methods such as spin drying, heat drying, warm air drying, and vacuum drying can be used. A suitable example thereof includes spin drying under blowing of inert gas (such as nitrogen gas).

### EXAMPLES

Hereinafter, the present invention will be described in more detail using examples, but is not limited to these examples.

<Preparation of Surface Treatment Agent>

### Examples 1 to 17 and Comparative Examples 1 and 2

A surface treatment agent of each example was prepared by mixing components shown in Tables 1 and 2 with each other.

TABLE 1

| | Component (A) | Component (S) | Component (B) |
|---|---|---|---|
| Example 1 | (A)-1 [3.0] | (S)-1 [96.7] | (B)-1 [0.3] |
| Example 2 | (A)-1 [5.0] | (S)-1 [95.0] | — |
| Example 3 | (A)-2 [5.0] | (S)-1 [95.0] | — |
| Comparative | (A)-1 [8.0] | (S)-2 [92.0] | — |
| Example 1 | | | |
| Comparative | (A)-2 [10] | (S)-2 [89.0] | (B)-2 [1.0] |
| Example 2 | | | |

TABLE 2

| | Component (A) | Component (S) | Component (B) |
|---|---|---|---|
| Example 4 | (A)-2 [10] | (S)-1 [89.0] | (B)-3 [1.0] |
| Example 5 | (A)-2 [10] | (S)-1 [89.0] | (B)-4 [1.0] |
| Example 6 | (A)-2 [10] | (S)-1 [89.0] | (B)-1 [1.0] |
| Example 7 | (A)-2 [10] | (S)-1 [89.0] | (B)-2 [1.0] |
| Example 8 | (A)-2 [10] | (S)-1 [89.0] | (B)-5 [1.0] |
| Example 9 | (A)-2 [10] | (S)-1 [89.0] | (B)-6 [1.0] |
| Example 10 | (A)-2 [10] | (S)-1 [89.0] | (B)-7 [1.0] |
| Example 11 | (A)-1 [10] | (S)-1 [89.0] | (B)-3 [1.0] |
| Example 12 | (A)-1 [10] | (S)-1 [89.0] | (B)-4 [1.0] |
| Example 13 | (A)-1 [10] | (S)-1 [89.0] | (B)-1 [1.0] |
| Example 14 | (A)-1 [10] | (S)-1 [89.0] | (B)-2 [1.0] |
| Example 15 | (A)-1 [10] | (S)-1 [89.0] | (B)-5 [1.0] |
| Example 16 | (A)-1 [10] | (S)-1 [89.0] | (B)-6 [1.0] |
| Example 17 | (A)-1 [10] | (S)-1 [89.0] | (B)-7 [1.0] |

In Tables 1 and 2, each abbreviation has the following meaning. The numerical values in [ ] represent formulation amount (mass %).

(A)-1: N,N-Dimethylaminotrimethylsilane (TMSDMA)

(A)-2: Hexamethyldisilazane (HMDS)

(S)-1: n-Decane

(S)-2: Propylene glycol monomethyl ether

(B)-1: 1,2,4-Triazole

(B)-2: 1,2,3-Benzotriazole

(B)-3: Pyrrole

(B)-4: Imidazole

(B)-5: 1H-Tetrazole

(B)-6: 5-Methyl-1H-tetrazole

(B)-7: 5-Benzyl-1H-tetrazole

[Evaluation of Resistance of Polyvinyl Chloride (PVC) to Surface Treatment Agent]

50 mL of each surface treatment agent of examples and comparative examples was added to a 100 mL bottle made of fluorine resin (PFA) and a polyvinyl chloride test piece (FMET4323, a thickness of about 3 mm, a size of 20 mm×30 mm, manufactured by TAKIRON Corporation) was immersed therein. The test piece was checked after two weeks to check whether or not there was any change in the test piece through visual observation and weight and size measurement. The results are shown in Tables 3 and 4.

<Surface Treatment Method of Object to be Treated>

A silicon nitride substrate (SiN) was used for an object to be treated. The silicon nitride substrate was fragmented to manufacture a chip for measurement which was then immersed in a hydrofluoric acid aqueous solution with a concentration of 1 mass % for 1 minute at 25° C. Subsequently, the chip was washed with pure water for 1 minute. The washed chip was dried in a nitrogen stream, and the dried chip was subjected to SC1 treatment. Subsequently, the SC1-treated chip was washed with pure water for 1 minute. Subsequently, the chip washed with water was dried in a nitrogen stream.

The surface of the dried chip was immersed in each surface treatment agent shown in Examples 1 to 17 and Comparative Examples 1 and 2 for 20 seconds at room temperature for surface treatment. Thereafter, the surface-treated chip was immersed in isopropyl alcohol for 1 minute at room temperature and finally dried in a nitrogen stream.

[Evaluation of Contact Angle]

Pure water droplets (2.0 μL) were added dropwise to the surface of an object to be treated of which the surface was treated through the above-described <Surface Treatment Method of Object to be Treated> and the contact angle 10 seconds after the dropwise addition was measured. The measurement results of the contact angle are shown in Tables 3 and 4. As a result of measuring the contact angle of each object to be treated before the surface treatment in the same manner, it was 14.0° in all cases.

TABLE 3

| | Change in | Contact |
|---|---|---|
| | member | angle (°) |
| Example 1 | No change | 62.8 |
| Example 2 | No change | 48.6 |
| Example 3 | No change | 33.1 |
| Comparative | Swollen | 51.3 |
| Example 1 | | |
| Comparative | Swollen | 62.8 |
| Example 2 | | |

TABLE 4

| | Change in | Contact |
|---|---|---|
| | member | angle (°) |
| .Example 4 | No change | 25.6 |
| Example 5 | No change | 32.2 |
| Example 6 | No change | 36.9 |
| Example 7 | No change | 61.7 |
| Example 8 | No change | 64.1 |
| Example 9 | No change | 59.2 |
| Example 10 | No change | 53.1 |
| Example 11 | No change | 51.5 |
| Example 12 | No change | 60.5 |
| Example 13 | No change | 63.1 |
| Example 14 | No change | 60.6 |
| Example 15 | No change | 68.1 |
| Example 16 | No change | 61.6 |
| Example 17 | No change | 61.4 |

As can be seen from Tables 3 and 4, in the surface treatment agents of Examples 1 to 17, it is possible to increase the contact angle of water on the surface of the object to be treated from 14.0° to 25.6° to 68.1° without changing the polyvinyl chloride test pieces.

On the other hand, the surface treatment agents of Comparative Examples 1 and 2 made the polyvinyl chloride test pieces swell.

From the above, according to the surface treatment agents of the examples, it was confirmed that it is possible to impart water repellency (silylation) to the surface of an object to be treated at a high level while suppressing deterioration in a liquid-contact portion.

Preferred examples of the present invention have described above, but the present invention is not limited to the examples. Addition, omission, replacement, and other modifications of the configurations can be made within the scope not departing from the gist of the present invention. The present invention is not limited by the above-described description, but is limited only by the scope of the accompanied claims.

What is claimed is:

1. A surface treatment agent comprising a silylating agent (A) and a solvent (S), wherein the solvent (S) comprises an aliphatic hydrocarbon (S1).

2. The surface treatment agent according to claim 1, wherein the aliphatic hydrocarbon (S1) has 6 to 20 carbon atoms.

3. The surface treatment agent according to claim 1, further comprising a nitrogen-containing basic compound or a salt thereof (B).

4. The surface treatment agent according to claim 3, wherein the nitrogen-containing basic compound or the salt thereof (B) comprises a nitrogen-containing heterocyclic compound or a salt thereof (B1).

5. The surface treatment agent according to claim 1, wherein the silylating agent (A) contains a compound (A2) having a hydrophobic group bonded to a silicon atom and a leaving group bonded to the silicon atom.

6. The surface treatment agent according to claim 5, wherein the compound (A2) comprises a compound represented by general formula (2) shown below: 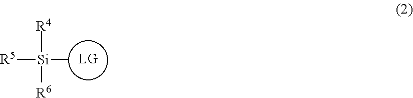
wherein R⁴, R⁵, and R⁶ each independently represent a hydrogen atom, a nitrogen-containing group, or an organic group, and the total number of carbon atoms contained in R⁴, R⁵, and R⁶ is greater than or equal to 1; and LG represents a leaving group.

7. The surface treatment agent according to claim 1, wherein the aliphatic hydrocarbon (S1) contains a linear aliphatic hydrocarbon having 8 to 12 carbon atoms.

8. The surface treatment agent according to claim 1, wherein the aliphatic hydrocarbon (S1) contains at least one selected from the group consisting of n-octane, n-nonane, n-decane, n-undecane, and n-dodecane.

9. The surface treatment agent according to claim 4, wherein the nitrogen-containing heterocyclic compound or a salt thereof (B1) contains at least one selected from the group consisting of pyrrole, imidazole, triazole, tetrazole which may have an alkyl group or an aryl group, and benzotriazole which may have an alkyl group or an aryl group.

10. A surface treatment method comprising subjecting an object to be treated to surface treatment using the surface treatment agent according to claim 1.

11. The surface treatment agent according to claim 2, further comprising a nitrogen-containing basic compound or a salt thereof (B).
